(19) United States
(12) Patent Application Publication
(10) Pub. No.: US 2025/0125206 A1
(43) Pub. Date: Apr. 17, 2025

(54) CHIP PACKAGE AND METHOD OF MANUFACTURING THE SAME

(71) Applicant: POWERTECH TECHNOLOGY INC., Hsinchu County (TW)

(72) Inventor: SHANG YU CHANG CHIEN, Hsinchu County (TW)

(21) Appl. No.: 18/814,595

(22) Filed: Aug. 26, 2024

(30) Foreign Application Priority Data
Oct. 16, 2023 (TW) 112139334

(51) Int. Cl. H01L 23/31; H01L 21/56; H01L 23/00; H01L 23/498; H01L 23/538; H01L 23/552; H01L 25/16

(52) U.S. Cl. CPC H01L 23/3107; H01L 21/563; H01L 23/552; H01L 24/24; H01L 25/162; H01L 23/49811; H01L 23/538; H01L 24/16; H01L 24/32; H01L 24/33; H01L 24/73; H01L 2224/16225; H01L 2224/24146; H01L 2224/32145; H01L 2224/32225; H01L 2224/33181; H01L 2224/73204; H01L 2224/73267

(57) ABSTRACT

A chip package includes a carrying part, an electronic component, solders, and a filling glue. The carrying part includes an insulating layer and a wiring structure layer disposed on the insulating layer while a first sidewall of the carrying part exposes the wiring structure layer and the insulating layer. The electronic component is disposed on the wiring structure layer. A gap is formed between the electronic component and the wiring structure layer. The solders disposed in the gap are connected to the electronic component and the wiring structure layer. The filling glue covers the wiring structure layer and the side of the electronic component and fills the gap. The filling glue has a second sidewall flush with the first sidewall of the carrying part and a top surface surrounding by the second sidewall and extending from the side of the electronic component to the second sidewall.

### CROSS-REFERENCE TO RELATED APPLICATION

This application claims priority to Taiwan Application Serial Number 112139334, filed Oct. 16, 2023, which is herein incorporated by reference in its entirety.

### BACKGROUND

### Field of Invention

The present disclosure relates to a chip package and a method of manufacturing the same. More particularly, the present disclosure relates to a chip package including a filling glue and a manufacturing method thereof.

### Description of Related Art

A conventional chip packages usually includes a chip, a carrier, a molding compound and an underfill. Generally, the chip, the underfill and the molding compound are all disposed on the carrier, where the bottom surface of the chip faces the carrier, and the underfill is disposed between the bottom surface of the chip and the carrier. The molding compound covers the entire chip and the underfill. That is, the top and the side of the chip are covered by the molding compound, so that the thickness of the molding compound is greater than the thickness of the chip. In other words, the overall thickness of the conventional chip package includes not only the thickness of the chip, but also the thickness of the part of the molding compound located on the top of the chip.

### SUMMARY

At least one embodiment of the present disclosure provides a chip package, which can have a thinner thickness and is conducive to the trend of thinning chip packages.

At least another embodiment of the present disclosure provides a method of manufacturing the chip package.

The chip package according to at least one embodiment of the present disclosure includes a carrying part, a first electronic component, multiple first solders, and a filling glue. The carrying part has a first sidewall and includes a first wiring structure layer and a first insulating layer, where the first wiring structure layer is disposed on the first insulating layer, and the first sidewall exposes the first wiring structure layer and the first insulating layer. The first electronic component is disposed on the first wiring structure layer, where a gap is formed between the first electronic component and the first wiring structure layer. The first solders are disposed in the gap and connected to the first electronic component and the first wiring structure layer. The filling glue covers the first wiring structure layer and a side of the first electronic component and fills the gap. The filling glue has a top surface and a second sidewall surrounding and connected to the top surface, where the second sidewall is flush with the first sidewall, and the top surface extends from the side of the first electronic component to the second sidewall.

The method of manufacturing the chip package according to at least another embodiment of the present disclosure includes the following steps. An initial carrying part is formed, where the initial carrying part includes a first wiring structure layer and a first insulating layer, and the first wiring structure layer is disposed on the first insulating layer. At least one first electronic component is disposed on the first wiring structure layer, where a gap is formed between the at least one first electronic component and the first wiring structure layer. After the at least one first electronic component is disposed on the first wiring structure layer, a filling material is formed on the first wiring structure layer, where the filling material covers a side of the at least one first electronic component and filling the gap. After the filling material is formed, the filling material and the initial carrying part are cut to form at least one carrying part and at least one filling glue disposed on the at least one carrying part.

Based on the above description, since the filling glue does not cover the upper surface of the first electronic component, the chip package has a thinner overall thickness, which is conducive to the trend of thinning the chip package.

### BRIEF DESCRIPTION OF THE DRAWINGS

FIG. 1A is a schematic cross-sectional view of a chip package according to at least one embodiment of the present disclosure.

FIG. 1B is an enlarged view of region 1B in FIG. 1A.

FIGS. 2A to 2G are schematic cross-sectional views of a method of manufacturing the chip package in FIG. 1A.

FIG. 3A is a schematic cross-sectional view of a chip package according to at least another embodiment of the present disclosure.

FIG. 3B is a schematic cross-sectional view of a step of a method of manufacturing the chip package in FIG. 3A.

FIG. 4A is a schematic cross-sectional view of a chip package according to at least another embodiment of the present disclosure.

FIG. 4B is a schematic cross-sectional view of a chip package according to at least another embodiment of the present disclosure.

FIG. 5 is a schematic cross-sectional view of a chip package according to at least another embodiment of the present disclosure.

FIG. 6 is a schematic cross-sectional view of a chip package according to at least another embodiment of the present disclosure.

### DETAILED DESCRIPTION

In the following description, in order to clearly present the technical features of the present disclosure, the dimensions (such as length, width, thickness, and depth) of elements (such as layers, films, substrates, and areas) in the drawings will be enlarged in unequal proportions. Therefore, the description and explanation of the following embodiments are not limited to the sizes and shapes presented by the elements in the drawings, but should cover the sizes, shapes, and deviations of the two due to actual manufacturing processes and/or tolerances. For example, the flat surface shown in the drawings may have rough and/or non-linear characteristics, and the acute angle shown in the drawings may be round. Therefore, the elements presented in the drawings in this case are mainly for illustration, and are not intended to accurately depict the actual shape of the elements, nor are they intended to limit the scope of patent applications in this case.

Furthermore, the words “about”, “approximately” or “substantially” used in the present disclosure not only cover the clearly stated numerical values and numerical ranges, but also cover those that can be understood by a person with ordinary knowledge in the technical field to which the present disclosure belongs. The permissible deviation range can be determined by the error generated during measurement, and the error is caused, for example, by limitations of the measurement system or process conditions. In addition, “about” may mean within one or more standard deviations of the above values, such as within ±30%, ±20%, ±10%, or ±5%. Such words as “about”, “approximately”, or “substantially” as appearing in the present disclosure may be used to select an acceptable range of deviation or standard deviation according to optical properties, etching properties, mechanical properties, or other properties, rather than applying all of the above optical properties, etching properties, mechanical properties, and other properties with a single standard deviation.

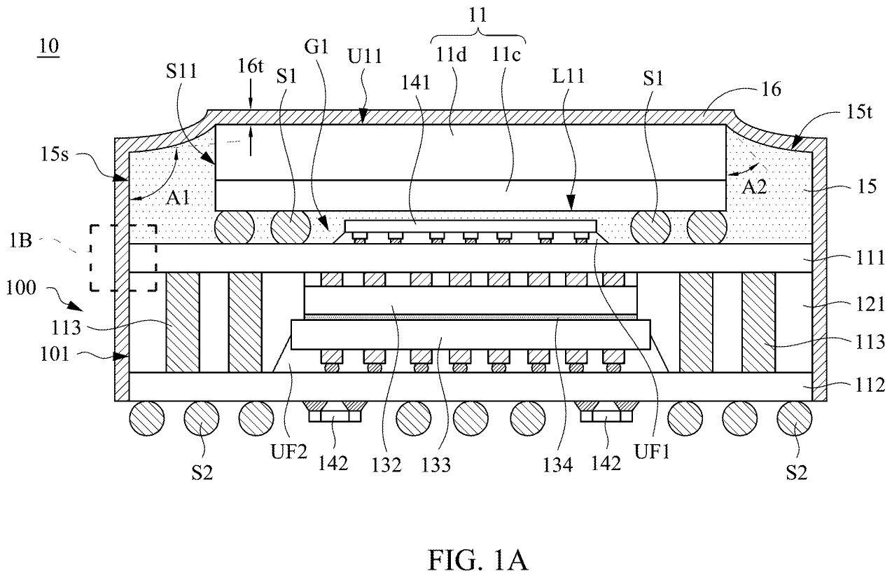

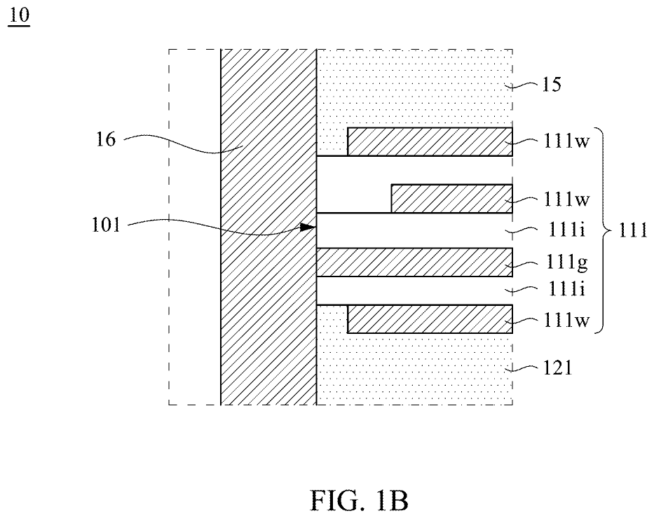

FIG. 1A is a schematic cross-sectional view of a chip package according to at least one embodiment of the present disclosure. Referring to FIG. 1A, the chip package 10 includes a first electronic component 11 and a carrying part 100, where the first electronic component 11 is disposed on the carrying part 100. In the embodiment shown in FIG. 1A, the carrying part 100 includes a first wiring structure layer 111 and a first insulating layer 121, where the first wiring structure layer 111 is disposed on the first insulating layer 121. In addition, the carrying part 100 has a first sidewall 101, and the first sidewall 101 exposes the first wiring structure layer 111 and the first insulating layer 121, as shown in FIG. 1A.

The first electronic component 11 is disposed on the first wiring structure layer 111 and is electrically connected to the first wiring structure layer 111, so the first wiring structure layer 111 is located between the first electronic component 11 and the first insulating layer 121. The first wiring structure layer 111 may be a redistribution layer (RDL), so the first wiring structure layer 111 may include at least one wiring layer and at least one insulating layer (neither shown in FIG. 1A). The first insulating layer 121 may be a ceramic layer or a polymer material layer, where the polymer material layer is, for example, a resin layer. In addition, the first insulating layer 121 may have photosensitivity. For example, the first insulating layer 121 may be a photo-imagable dielectric (PID) material.

In the embodiment shown in FIG. 1A, the chip package 10 further includes multiple first solders S1, where the first solders S1 are disposed between the first electronic component 11 and the first wiring structure layer 111 and connect to the first electronic component 11 and the first wiring structure layer 111 so that the first electronic component 11 can be electrically connected to the first wiring structure layer 111 through the first solders S1. In addition, the first solders S1 can support the first electronic component 11 so that a gap G1 is formed between the first electronic component 11 and the first wiring structure layer 111, where the first solders S1 are disposed in the gap G1.

In the embodiment shown in FIG. 1A, the first electronic component 11 may be a packaged component. Specifically, the first electronic component 11 may include a carrier 11c and a chip element 11d, where the chip element 11d is mounted on the carrier 11c, and the chip element 11d may be a packaged chip. In addition, in other embodiments, the first electronic component 11 may also be an unpackaged die. That is, the carrier 11c shown in FIG. 1A can be omitted, and the unpackaged chip element 11d can be directly connected to the first solders S1 so that the chip element 11d can be electrically connected to the first wiring structure layer 111 only through the first solders S1 without the carrier 11c.

It is worth noting that in other embodiments, the first electronic component 11 may be a multi-chip package, such as a system-in-package (SiP). Thus, the first electronic component 11 may include at least two chips, where the aforementioned chips may be packaged chips or unpackaged dies. Therefore, the number of chips (such as packaged chips or unpackaged dies) included in the first electronic component 11 can be multiple, and is not limited to only one.

The chip package 10 further includes a filling glue 15, where the filling glue 15 covers a surface of the first wiring structure layer 111 and a surface of the first electronic component 11, and fills the gap G1. The filling glue 15 may be an underfill, not a molding compound. Alternatively, the filling glue 15 may be a molding compound, not an underfill. The first electronic component 11 has an upper surface U11, a lower surface L11 and a side S11, where the upper surface U11 and the lower surface L11 are opposite to each other, and the side S11 surrounds and is connected to the upper surface U11 and the lower surface L11. As shown in FIG. 1A, the chip element 11d has the upper surface U11, and the carrier 11c has the lower surface L11, where the side S11 includes sides of both the chip element 11d and the carrier 11c, and the first solders S1 are connected to the lower surface L11.

The filling glue 15 covers at least a portion of the side S11 of the first electronic component 11. Taking FIG. 1A as an example, the filling glue 15 can completely cover the side S11 of the first electronic component 11 so that the filling glue 15 surrounds the first electronic component 11 but does not cover the upper surface U11. In other words, the filling glue 15 is connected an edge of the upper surface U11 of the first electronic component 11. The filling glue 15 has a top surface 15t and a second sidewall 15s, where the second sidewall 15s is flush with the first sidewall 101. The second sidewall 15s surrounds and is connected to the top surface 15t. Since the filling glue 15 does not cover the upper surface U11 of the first electronic component 11, the top surface 15t of the filling glue 15 surrounds the upper surface U11 and extends from the side S11 of the first electronic component 11 to the second sidewall 15s.

The filling glue 15 has an included angle A1 between the top surface 15t and the second sidewall 15s, where the included angle A1 is greater than 90 degrees. The distance between the top surface 15t and the carrying part 100 decreases from the side S11 of the first electronic component 11 toward the second sidewall 15s, so the top surface 15t is a slope, as shown in FIG. 1A. In the embodiment shown in FIG. 1A, the top surface 15t may be a concave curve. In other embodiments, the top surface 15t may be a flat surface. An included angle A2 between the top surface 15t and the side S11 may be less than 90 degrees, where the included angle A2 is the contact angle between the filling glue 15 and the side S11 of the first electronic component 11. In addition, the dotted line in FIG. 1A represents the tangent line of the top surface 15t, in which the dotted line of the included angle A1 extends from the edge of the second sidewall 15s, and the dotted line of the included angle A2 extends from the side S11 (for example, the edge of the side S11).

In the embodiment shown in FIG. 1A, the carrying part 100 further includes chips: a first chip 132 and a second chip 133. The first chip 132 and the second chip 133 are both disposed in the first insulating layer 121, where the first chip 132 is electrically connected to the first wiring structure layer 111, and the first chip 132 is located between the second chip 133 and the first wiring structure layer 111. In addition, similar to the first electronic component 11, at least one of the first chip 132 and the second chip 133 may be a packaged component or an unpackaged die.

The carrying part 100 further includes an adhesive layer 134, where the adhesive layer 134 is disposed between the first chip 132 and the second chip 133, and adheres to a backside of the first chip 132 and a backside of the second chip 133 so that the first chip 132 and the second chip 133 can be bonded to each other. In addition, the adhesive layer 134 is an insulator, so the first chip 132 and the second chip 133 cannot be electrically connected to each other through the adhesive layer 134.

The carrying part 100 further includes a second wiring structure layer 112 electrically connected to the second chip 133, where the second chip 133 can be electrically connected to the second wiring structure layer 112 through solders (not labeled). The second chip 133 is located between the first chip 132 and the second wiring structure layer 112, so the first chip 132 is located between the second chip 133 and the first electronic component 11. The first insulating layer 121 is sandwiched between the first wiring structure layer 111 and the second wiring structure layer 112. Therefore, the first chip 132 and the second chip 133 disposed in the first insulating layer 121 are located between the first wiring structure layer 111 and the second wiring structure layer 112. In addition, the gap (not labeled) between the second chip 133 and the second wiring structure layer 112 may be filled with an underfill UF2, as shown in FIG. 1A.

The carrying part 100 further includes at least one conductive pillar 113. Taking FIG. 1A as an example, the carrying part 100 includes multiple conductive pillars 113, and the conductive pillars 113 are disposed in the first insulating layer 121. Each conductive pillar 113 may be cylindrical in shape and substantially have a fixed diameter. The conductive pillars 113 are located between the first wiring structure layer 111 and the second wiring structure layer 112 and connected to the first wiring structure layer 111 and the second wiring structure layer 112.

In this way, each conductive pillar 113 can electrically connect to the first wiring structure layer 111 and the second wiring structure layer 112 so that the first wiring structure layer 111 and the second wiring structure layer 112 can be electrically connected to each other through the conductive pillar 113. In addition, using the first wiring structure layer 111, the second wiring structure layer 112, and the conductive pillars 113, the first electronic component 11, the first chip 132, and the second chip 133 can be electrically connected to each other to allow electrical signals to be transmitted between the first electronic component 11, the first chip 132, and the second chip 133.

It should be noted that, in the embodiment shown in FIG. 1A, the carrying part 100 includes multiple conductive pillars 113. However, in other embodiments, the number of conductive pillars 113 included in the carrying part 100 may be only one. Therefore, the conductive pillars 113 shown in FIG. 1A are only for illustration and do not limit the number of the conductive pillars 113 included in the carrying part 100.

Furthermore, in the embodiment shown in FIG. 1A, the carrying part 100 is a package that includes at least one chip (e.g., the first chip 132 and the second chip 133) but in other embodiments, the carrying part 100 may also be a carrier or circuit board that does not include any chip or die. Therefore, the carrying part 100 shown in FIG. 1A is for illustration and is not limited to a chip package.

The second wiring structure layer 112 may also be a redistribution layer (RDL), so the second wiring structure layer 112 may also include at least one wiring layer and at least one insulating layer (neither shown). In at least one embodiment, the first wiring structure layer 111 and the second wiring structure layer 112 may have the same number of wiring layers. However, in other embodiments, the difference in the number of wiring layers between the first wiring structure layer 111 and the second wiring structure layer 112 can be used to avoid or weaken the warpage of the carrying part 100 due to a mismatch of CTE (coefficient of thermal expansion). Therefore, the first wiring structure layer 111 and the second wiring structure layer 112 may have different numbers of wiring layers.

In at least one embodiment, the thickness of the insulating layer or the thickness of the wiring layer of the first wiring structure layer 111 and the second wiring structure layer 112 may be substantially the same as each other. When the aforementioned thickness of the insulating layer or the aforementioned thickness of wiring layer of the first wiring structure layer 111 and the second wiring structure layer 112 are substantially the same as each other, the thickness of the insulating layer or the thickness of wiring layer of the first wiring structure layer 111 and the second wiring structure layer 112 may be slightly different from each other within a permissible tolerance range. Alternatively, in other embodiments, the thickness of the insulating layer or the thickness of the wiring layer may be significantly different between the first wiring structure layer 111 and the second wiring structure layer 112 to avoid or weaken the warpage of the carrying part 100 due to differences in the coefficients of thermal expansion.

The chip package 10 may further include at least one second electronic component, where the second electronic component may be disposed on at least one of the first wiring structure layer 111 and the second wiring structure layer 112. Taking FIG. 1A as an example, the chip package 10 includes second electronic components 141 and 142, where the second electronic component 141 is disposed on the first wiring structure layer 111, and the second electronic component 142 is disposed on the second wiring structure layer 112.

As shown in FIG. 1A, the second electronic component 141 is located on the upper surface of the first wiring structure layer 111, and the second electronic component 142 is located on the lower surface of the second wiring structure layer 112, where the second electronic component 141 is located in the gap G1 and covered by filling glue 15. The second electronic component 141 can be soldered to the first wiring structure layer 111, and the gap (not labeled) between the second electronic component 141 and the first wiring structure layer 111 can be filled with underfill UF1. In addition, at least one of the second electronic components 141 and 142 may be a passive component, such as a resistor, a capacitor or an inductor.

The chip package 10 further includes an EMI shielding layer 16, where the EMI shielding layer 16 conformally covers the first electronic component 11, the first sidewall 101 of the carrying part 100, the top surface 15t and the second sidewall 15s of the filling glue 15 so that the EMI shielding layer 16 and the second wiring structure layer 112 cover the first electronic component 11, the first chip 132 and the second chip 133. In addition, the EMI shielding layer 16 may be a metal layer, such as a copper metal layer, and the EMI shielding layer 16 may have a relatively thin thickness 16t, such as between 1 micrometer and 5 micrometers.

FIG. 1B is an enlarged view of region 1B in FIG. 1A. Referring to FIGS. 1A and 1B, in the embodiment shown in FIG. 1B, the first wiring structure layer 111 includes wiring layers 111g, 111w and insulating layers 111i, where the wiring layers 111g, 111w and insulating layers 111i are stacked on each other, and each insulating layer 111i is sandwiched between two of the adjacent layers of the wiring layers 111g and 111w. In other embodiment, an insulating layer 111i may be between the filling glue 15 and the wiring layer 111w, and another insulating layer 111i may be between the first insulating layer 121 and the wiring layer 111w.

The EMI shielding layer 16 is connected to and contacts the wiring layer 111g, where the wiring layer 111g is a ground layer, such as a ground plane. Specifically, one side of the wiring layer 111g is exposed to the first sidewall 101 so that the EMI shielding layer 16 covering the first sidewall 101 can contact and connect to the wiring layer 111g. In this way, the EMI shielding layer 16 is electrically connected to the wiring layer 111g and grounded so that the EMI shielding layer 16 effectively shields the electromagnetic waves. In addition, the EMI shielding layer 16 electrically connects only the wiring layer 111g but does not electrically connect the wiring layer 111w used for transmitting the electrical signals, in order to avoid short-circuiting between the wiring layer 111w and the EMI shielding layer 16.

It should be noted that in other embodiments, the first wiring structure layer 111 may include only one wiring layer 111w and may not include any ground layer so that the EMI shielding layer 16 is not electrically connected to the first wiring structure layer 111. Therefore, the EMI shielding layer 16 and the first wiring structure layer 111 disclosed in FIG. 1B are only for illustration and do not limit the number of wiring layers 111w and 111g in the first wiring structure layer 111.

Based on the above description, since the filling glue 15 does not cover the upper surface U11 of the first electronic component 11, and the EMI shielding layer 16 has a considerably thin thickness 16t. Accordingly, the chip package 10 may have a thinner overall thickness as compared to conventional packages, so as to make the chip package 10 favorable for thinning, thereby meeting the development trend of conventional electronic devices.

As shown in FIG. 1A, the filling glue 15 has a certain amount of content and occupies a considerable proportion in the entire chip package 10, such that the filling glue 15 affects the warpage of the chip package 10. Therefore, the warpage of the chip package 10 can be avoided or weakened by adjusting the content of the filling glue 15 or selecting a filling glue 15 with a suitable coefficient of thermal expansion. In addition, the filling glue 15 may be mixed with heat dissipation material to help dissipate heat from the chip package 10, thereby maintaining or enhancing the performance of the chip package 10.

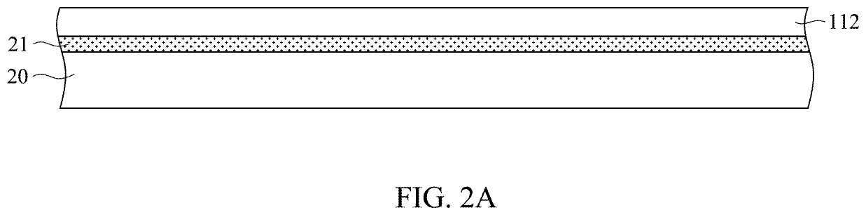

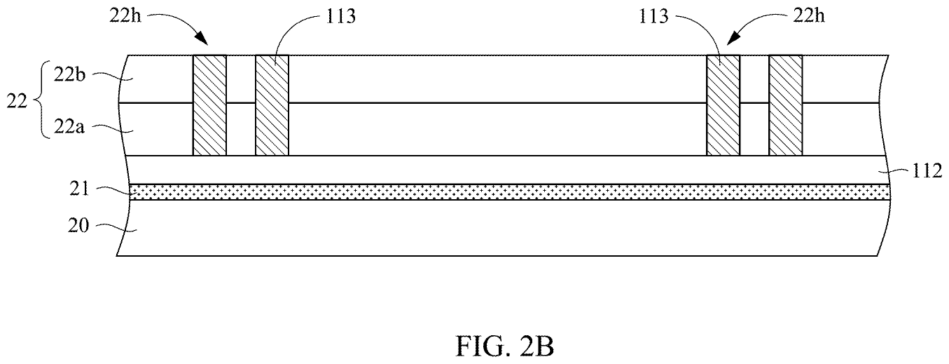

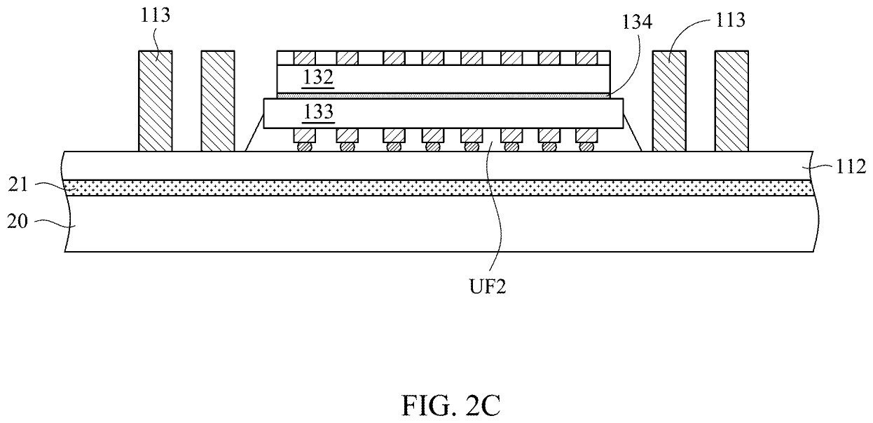

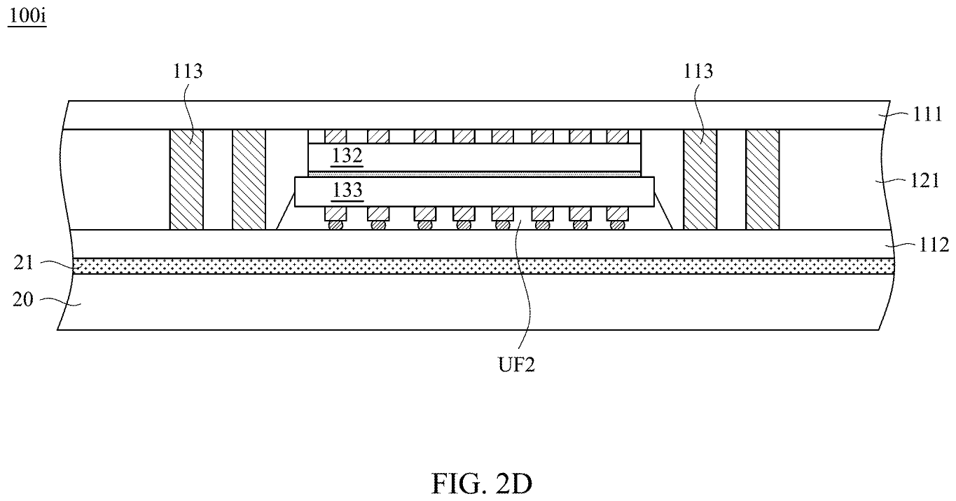

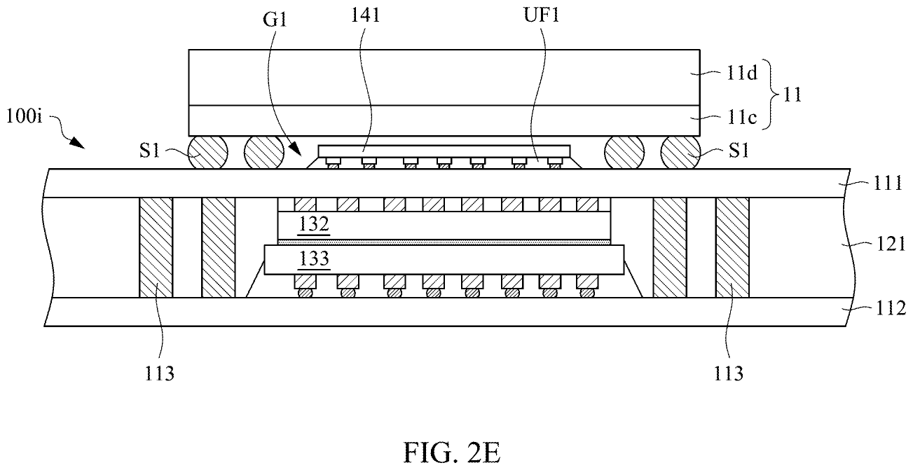

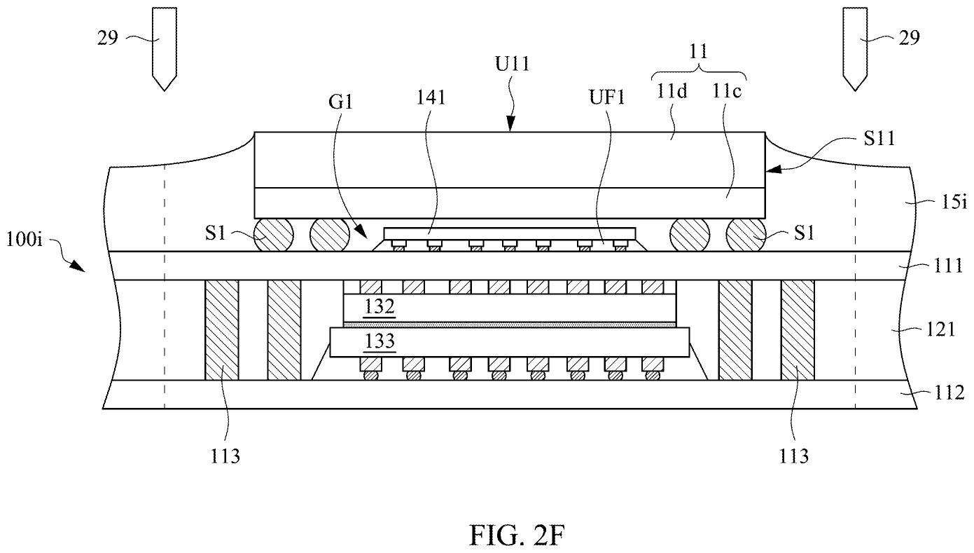

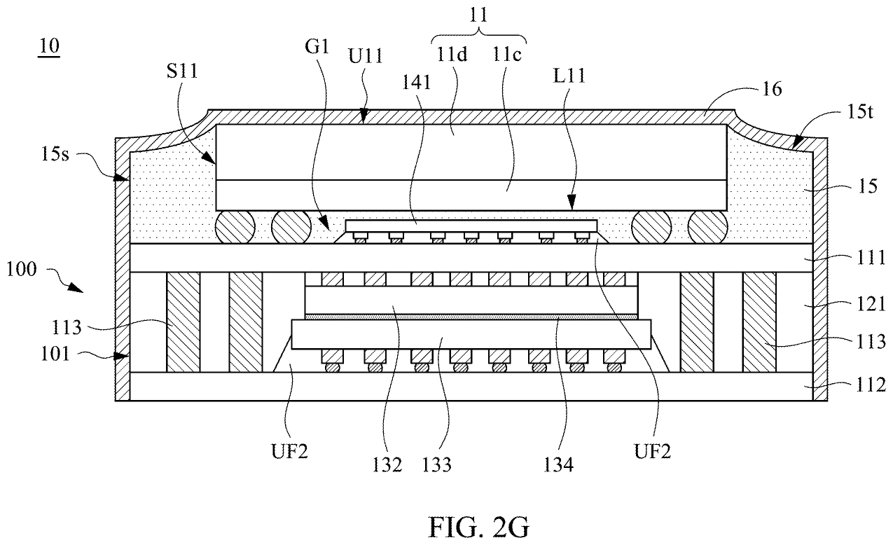

FIGS. 2A to 2G are schematic cross-sectional views of a method of manufacturing the chip package in FIG. 1A. Referring to FIG. 2A, in the method of manufacturing the chip package 10, firstly, a second wiring structure layer 112 is formed on the carrier substrate 20. The carrier substrate 20 may be a rigid substrate, which is, for example, a glass substrate or a metal substrate, and the wiring layer of the second wiring structure layer 112 may be formed by using an additive method, semi-additive, or subtractive method.

In the embodiment shown in FIG. 2A, the dimensions (e.g., length, width, or area) of both the carrier substrate 20 and the second wiring structure layer 112 may be equivalent to the dimensions of a wiring panel or a substrate strip. Thus, the dimensions of both the carrier substrate 20 and the second wiring structure layer 112 in FIG. 2A may be significantly larger than the dimensions of a single chip package 10.

It should be noted that in other embodiments, the dimensions of both the carrier substrate 20 and the second wiring structure layer 112 may be equivalent to the dimension of the substrate unit, so the dimensions of both the carrier substrate 20 and the second wiring structure layer 112 may be significantly smaller than the dimensions of the wiring panel or the substrate strip. Furthermore, in this embodiment, a release layer 21 may be formed on the carrier substrate 20 first. Thereafter, the second wiring structure layer 112 is formed on the release layer 21 to enable the carrier substrate 20 to be peeled off from the second wiring structure layer 112 in a subsequent process.

Referring to FIG. 2B, thereafter, at least one conductive pillar 113 is formed on the second wiring structure layer 112. Taking FIG. 2B as an example, multiple conductive pillars 113 are formed on the second wiring structure layer 112. Since the number of conductive pillars 113 included in the carrying part 100 of other embodiments may be only one, in the step shown in FIG. 2B, only one conductive pillar 113 may be formed on the second wiring structure layer 112.

In the process of forming the conductive pillars 113, a seed layer and a patterned mask layer 22 may be sequentially formed on the second wiring structure layer 112. The seed layer is a metal film and has a very thin thickness, so it is not shown in the drawing. The seed layer can be formed through deposition. For example, the seed layer can be formed by physical vapor deposition (PVD) such as sputtering or evaporation.

The patterned mask layer 22 may be a photoresist pattern after exposure and development, so the patterned mask layer 22 has one or more openings 22h, where the openings 22h partially expose the seed layer. The patterned mask layer 22 may have a multi-layer structure. Taking FIG. 2B as an example, the patterned mask layer 22 may include a first photoresist pattern 22a and a second photoresist pattern 22b, where the first photoresist pattern 22a is located between the second photoresist pattern 22b and the carrier substrate 20, and the opening 22h extends through the first photoresist pattern 22a and the second photoresist pattern 22b. In this embodiment, the first photoresist pattern 22a is formed by one exposure and one development, and the second photoresist pattern 22b is formed by another exposure and development process, that is, the opening 22h is formed by two exposures and two developments.

It should be noted that in other embodiments, the patterned mask layer 22 may only have a single-layer structure. In other words, the second photoresist pattern 22b in FIG. 2B can be omitted, so the opening 22h can be formed through only one exposure and only one development. In another embodiment, the patterned mask layer 22 may also include three or more layers of photoresist patterns, so the opening 22h may be formed through at least three exposures and at least three developments. Thereafter, the patterned mask layer 22 is used as a mask to form conductive pillars 113 on the second wiring structure layer 112. The conductive pillars 113 can be formed by electroplating using the above-mentioned seed layer.

It is worth noting that in this embodiment, the conductive pillars 113 are formed by using the seed layer and the patterned mask layer 22. However, in other embodiments, the conductive pillars 113 may also be formed without any seed layer and patterned mask layer 22. Specifically, the conductive pillars 113 can be fabricated metal pillars, such as copper pillars, and the conductive pillars 113 can be directly disposed on the second wiring structure layer 112, where the conductive pillars 113 can be welded to the wiring layer of the second wiring structure layer 112 so that the conductive pillars 113 are electrically connected to the second wiring structure layer 112.

Referring to FIG. 2C, after the conductive pillars 113 are formed, the patterned mask layer 22 and the seed layer are removed. The seed layer can be removed by etching, such as micro-etching. Thereafter, at least one first chip 132 and at least one second chip 133 are disposed on the second wiring structure layer 112, where the backside of the first chip 132 and the backside of the second chip 133 can be bonded to each other through an adhesive layer 134.

Since the dimensions of both the carrier substrate 20 and the second wiring structure layer 112 may be equivalent to the dimensions of the wiring panel or the substrate strip, the second wiring structure layer 112 can accommodate multiple first chips 132 and multiple second chips 133. That is, at least one first chip 132 and at least one second chip 133 may be disposed on the second wiring structure layer 112. After the first chip 132 and the second chip 133 are disposed on the second wiring structure layer 112, a gap (not labeled) is formed between the second chip 133 and the second wiring structure layer 112. At this time, an underfill UF2 can be filled into the aforementioned gap.

Referring to FIG. 2D, after forming the conductive pillars 113, the first chip 132 and the second chip 133, the first insulating layer 121 is formed on the second wiring structure layer 112. The first insulating layer 121 covers all the conductive pillars 113, all the first chips 132 and all the second chips 133, so the dimension of the first insulating layer 121 is also equivalent to the dimensions of the wiring panel or the substrate strip. However, in other embodiments, the dimensions of the carrier substrate 20 and the second wiring structure layer 112 may also be equivalent to the dimension of the substrate unit, so the dimension of the first insulating layer 121 may also be equivalent to the dimension of the substrate unit, and the first insulating layer 121 may only cover one first chip 132 and one second chip 133.

Thereafter, the first wiring structure layer 111 is formed on the first insulating layer 121 to form the initial carrying part 100i. The method of forming a wiring layer of the first wiring structure layer 111 (e.g., the wiring layer 111w in FIG. 1B) may be the same as the method of forming the wiring layer of the second wiring structure layer 112 and is not repeated. The initial carrying part 100i includes the first wiring structure layer 111, the first insulating layer 121, the conductive pillars 113, the first chip 132 and the second chip 133. The dimension of the initial carrying part 100i may be equivalent to the dimensions of the wiring panel or the substrate strip. Alternatively, the dimension of the initial carrying part 100i may be equivalent to the dimension of the substrate unit.

Referring to FIG. 2E, after the first wiring structure layer 111 is formed, the carrier substrate 20 is removed. In this embodiment, the carrier substrate 20 can be peeled off from the second wiring structure layer 112 through the release layer 21. Laser or heating can be used to detach the release layer 21 so that the carrier substrate 20 can be peeled off from the second wiring structure layer 112. In other embodiments, the carrier substrate 20 may be a metal substrate and may be removed by etching, where the second wiring structure layer 112 may be formed directly on the surface of the carrier substrate 20 without the need to form any release layer 21 on the carrier substrate 20. In other words, the release layer 21 shown in FIGS. 2A to 2D may be omitted.

Referring to FIG. 2E, thereafter, at least one first electronic component 11 and at least one second electronic component 141 are disposed on the first wiring structure layer 111, where first electronic component 11 and the second electronic component 141 can be disposed on the first wiring structure layer 111 in a flip-chip manner, and the gap between the second electronic component 141 and the first wiring structure layer 111 can be filled with an underfill UF1. Therefore, the first electronic component 11 can be disposed on the first wiring structure layer 111 using first solders S1.

Since the dimension of the initial carrying part 100i may be equivalent to the dimensions of the wiring panel or the substrate strip, the first wiring structure layer 111 of the initial carrying part 100i may provide at least one first electronic component 11 with at least one second electronic component 141 for installation. In addition, after the first electronic component 11 is disposed on the first wiring structure layer 111, a gap G1 between the first electronic component 11 and the first wiring structure layer 111 is formed, as shown in FIG. 2E.

Referring to FIG. 2F, thereafter, a filling material 15i is formed on the first wiring structure layer 111, where the filling material 15i comprehensively covers the upper surface of the initial carrying part 100i. The filling material 15i may be a glue material and covers all the sides S11 of the first electronic component 11, where the filling material 15i further fills the gap G1, as shown in FIG. 2F.

In this embodiment, the filling material 15i can completely cover the side S11 of the first electronic component 11 so that the filling material 15i surrounds the first electronic component 11 and is connected to the edge of the upper surface U11 of the first electronic component 11 but does not cover the upper surface U11. In other embodiments, the filling material 15i may not completely cover the side S11 of the first electronic component 11, that is, the filling material 15i covers a portion of the side S11 but does not cover other portion of the side S11. Therefore, the filling material 15i may not be connected to the edge of the upper surface U11.

After the filling material 15i is formed, the filling material 15i and the initial carrying part 100i are cut. Since the dimension of the initial carrying part 100i may be equivalent to the dimensions of the wiring panel or the substrate strip, the initial carrying part 100i can be cut into multiple carrying parts 100 and multiple filling glue 15 disposed on the carrying parts 100. After cutting the filling material 15i and the initial carrying part 100i, multiple chip packages 10 can be formed. In addition, the dimension of the initial carrying part 100i can also be equivalent to the dimension of the substrate unit, so the cut initial carrying part 100i can form only one carrying part 100 and one filling glue 15, that is, only one chip package 10 is formed.

Referring to FIGS. 2F and 2G, before cutting the filling material 15i, the filling material 15i can be solidified so that the cutter 29 can cut the filling material 15i smoothly, where the dotted line shown in FIG. 2F represents the cutting path of the cutter 29. Since both the filling material 15i and the initial carrying part 100i are cut by the cutter 29, after the cutter 29 cuts the filling material 15i and the initial carrying part 100i, the second sidewall 15s is flush with the first sidewall 101. In addition, in other embodiments, other means may also be used to cut the filling material 15i, such as laser cutting. Therefore, the use of the cutter 29 to cut the filling material 15i is not limited.

Referring to FIG. 2G, after cutting the filling material 15i and the initial carrying part 100i, an EMI shielding layer 16 can be formed, where the EMI shielding layer 16 covers the first electronic component 11, the carrying part 100 and the filling glue 15. The EMI shielding layer 16 can be formed by physical vapor deposition (PVD), such as sputtering or evaporation. Therefore, the EMI shielding layer 16 can conformally cover the upper surface U11 of the first electronic component 11, the first sidewall 101 of the carrying part 100, the top surface 15t and the second sidewall 15s of the filling glue 15.

Referring to FIGS. 1A and 2G, since the included angle A1 is greater than 90 degrees and the top surface 15t is an inclined plane, during the process of physical vapor deposition (such as sputtering), the metal material is conducive to being deposited on the top surface 15t of the filling glue 15 so that the EMI shielding layer 16 can comprehensively cover the upper surface U11 of the first electronic component 11, the first sidewall 101 of the carrying part 100, the top surface 15t and the second sidewall 15s of the filling glue 15. In this way, the EMI shielding layer 16 can effectively shield electromagnetic waves to reduce or avoid interference of electromagnetic waves on the first electronic component 11, the first chip 132 and the second chip 133.

After the EMI shielding layer 16 is formed, multiple second solders S2 and multiple second electronic components 142 may be disposed on the lower surface of the second wiring structure layer 112 to form the chip package 10 as shown in FIG. 1A. The second solders S2 enable the chip package 10 to be mounted on an external circuit board (not shown) so that the chip package 10 is electrically connected to the external circuit board.

It is particularly mentioned that in the above embodiments, the second solders S2 and the second electronic components 142 are disposed on the lower surface of the second wiring structure layer 112 after the EMI shielding layer 16 is formed. However, in other embodiments, the second solders S2 and the second electronic components 142 may be disposed on the lower surface of the second wiring structure layer 112 first. Thereafter, the EMI shielding layer 16 is formed. Therefore, the embodiments disclosed in FIGS. 1A and 2G do not limit the order of forming the EMI shielding layer 16 and disposing the second solders S2 and the second electronic components 142.

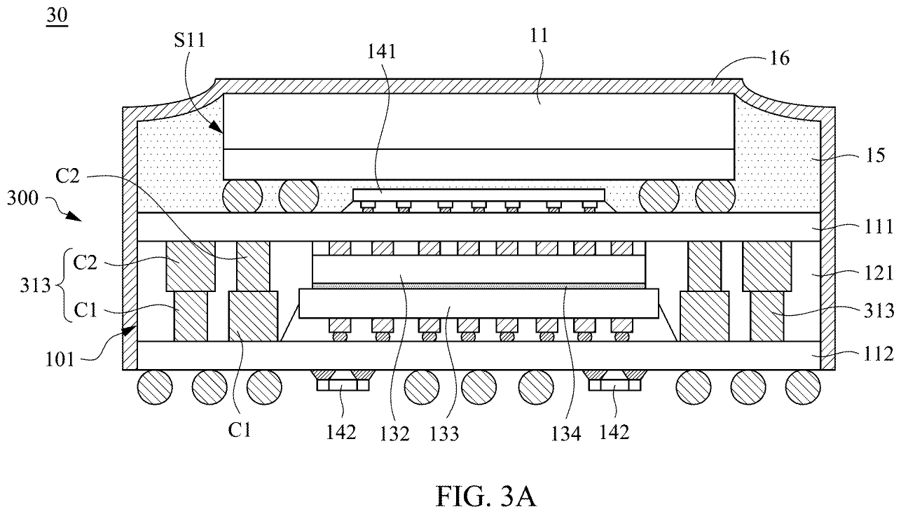

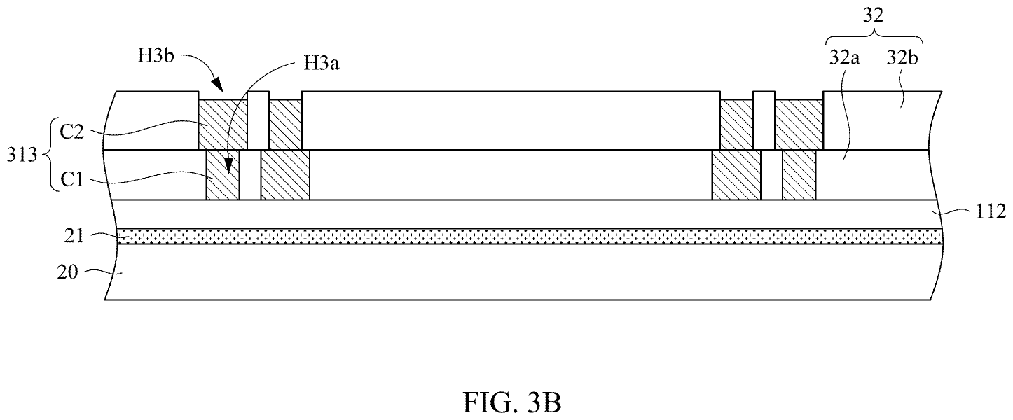

FIG. 3A is a schematic cross-sectional view of a chip package according to at least another embodiment of the present disclosure. Referring to FIG. 3A, the chip package 30 of this embodiment is similar to the aforementioned chip package 10. For example, the chip package 30 also includes the filling glue 15, the first electronic component 11 and the carrying part 300, and the carrying part 300 includes the first chip 132, the second chip 133, the first wiring structure layer 111, and the second wiring structure layer 112, the first insulating layer 121 and the second electronic components 141 and 142. The differences between the chip packages 30 and 10 are described below and the similar features of the chip packages 30 and 10 are not repeated.

Different from the chip package 10, the carrying part 300 includes at least one conductive pillar 313, where the conductive pillar 313 is different from the aforementioned conductive pillar 113. Taking FIG. 3A as an example, the carrying part 300 includes multiple conductive pillars 313, where each conductive pillar 313 includes a first conductive sub-pillar C1 and a second conductive sub-pillar C2, and the first conductive sub-pillar C1 is connected to the second wiring structure layer 112. Furthermore, in other embodiments, the carrying part 300 may include only one conductive pillar 313. Alternatively, the carrying part 300 may include at least one conductive pillar 113 and at least one conductive pillar 313. Therefore, FIG. 3A is only for illustration and does not limit the shape and number of the conductive pillars 313.

The second conductive sub-pillar C2 is stacked on the first conductive sub-pillar C1 and is connected to the first conductive sub-pillar C1 and the first wiring structure layer 111, so the second conductive sub-pillar C2 is located between the first conductive sub-pillar C1 and the first wiring structure layers 111. Through the conductive pillars 313, the first wiring structure layer 111 and the second wiring structure layer 112 can be electrically connected to each other.

As shown in FIG. 3A, in the same conductive pillar 313, the diameter of the first conductive sub-pillar C1 is not equal to the diameter of the second conductive sub-pillar C2. Taking FIG. 3A as an example, in the outermost conductive pillar 313, the diameter of the second conductive sub-pillar C2 is larger than the diameter of the first conductive sub-pillar C1, and the second conductive sub-pillar C2 protrudes from the side of the first conductive sub-pillar C1. In the innermost conductive pillar 313, the diameter of the second conductive sub-pillar C2 is smaller than the diameter of the first conductive sub-pillar C1, and the first conductive sub-pillar C1 protrudes from the side of the second conductive sub-pillar C2. Therefore, each conductive pillar 313 has significantly different diameters.

It is worth noting that, in the embodiment shown in FIG. 3A, the diameters of the first conductive sub-pillars C1 are not equal to each other, and the diameters of the second conductive sub-pillars C2 are also not equal to each other. However, in other embodiments, the diameters of the first conductive sub-pillars C1 may be equal to each other, and the diameters of the second conductive sub-pillars C2 may be equal to each other, where the diameters of the first conductive sub-pillars C1 are not equal to the second conductive sub-pillars C2. Therefore, the diameter of each second conductive sub-pillar C2 may be larger than the diameter of the first conductive sub-pillar C1. Alternatively, the diameter of each second conductive sub-pillar C2 may be smaller than the diameter of the first conductive sub-pillar C1.

FIG. 3B is a schematic cross-sectional view of a step of a method of manufacturing the chip package in FIG. 3A. Referring to FIG. 3B, the formation methods of conductive pillars 313 and 113 are similar but the only difference is that the patterned mask layer 32 used to form the conductive pillars 313 is different from the aforementioned patterned mask layer 22. Furthermore, the steps disclosed in FIG. 3B may be performed after the seed layer is formed on the second wiring structure layer 112 (as shown in FIG. 2A).

Forming the conductive pillars 313 may include the following steps. First, a first photoresist pattern 32a is formed on the second wiring structure layer 112, where the first photoresist pattern 32a partially exposes the seed layer (not shown) on the second wiring structure layer 112. Next, using the first photoresist pattern 32a as a mask, at least one first conductive sub-pillar C1 is formed on the second wiring structure layer 112. The first conductive sub-pillar C1 can be formed by electroplating using the seed layer.

After forming the first conductive sub-pillar C1, a second photoresist pattern 32b is formed on the first photoresist pattern 32a and the first conductive sub-pillar C1, where the second photoresist pattern 32b exposes the first conductive sub-pillar C1. Next, using the second photoresist pattern 32b as a mask, the second conductive sub-pillars C2 are formed on the first conductive sub-pillars C1. The second conductive sub-pillars C2 can also be formed by electroplating using the same seed layer under the first conductive sub-pillars C1.

The first photoresist pattern 32a and the second photoresist pattern 32b each have multiple openings H3a and H3b, where the diameters of at least two of the openings H3a and H3b are not equal so that the diameter of the first conductive sub-pillar C1 is not equal to the diameter of the second conductive sub-pillar C2 as shown in FIGS. 3A and 3B. In addition, in this embodiment, the first conductive sub-pillar C1 and the second conductive sub-pillar C2 of the same conductive pillar 313 may be substantially coaxial. However, in other embodiments, the first conductive sub-pillar C1 and the second conductive sub-pillar C2 of the same conductive pillar 313 may also be significantly non-coaxial.

It is worth mentioning that the first photoresist pattern 32a and the second photoresist pattern 32b are both developed photoresist layers, so the steps of forming both the first photoresist pattern 32a and the second photoresist pattern 32b include exposure and development. In other words, the formation method of the conductive pillar 313 disclosed in the above embodiment includes two exposures and two developments. However, in other embodiments, the conductive pillars 313 can also be formed by only one development. That is, the openings H3a and H3b can be formed by only one step development.

Specifically, two exposed photoresist layers may be sequentially formed on the second wiring structure layer 112. Then, the two photoresist layers are developed to form the first photoresist pattern 32a and the second photoresist pattern 32b as shown in FIG. 3B. Therefore, the first photoresist pattern 32a and the second photoresist pattern 32b having the openings H3a and H3b can be formed after the same development process. Thereafter, the seed layer on the second wiring structure layer 112 is electroplated to form the first conductive sub-pillar C1 and the second conductive sub-pillar C2, where the first conductive sub-pillar C1 and the second conductive sub-pillar C2 can be formed in the same electroplating process. The aforementioned two photoresist layers may both be positive photoresist layers or negative photoresist layers. Alternatively, the two photoresist layers may be a positive photoresist layer and a negative photoresist layer respectively. Moreover, if the two photoresist layers are different tone types, the openings H3a and H3b will be formed separately in different developing steps.

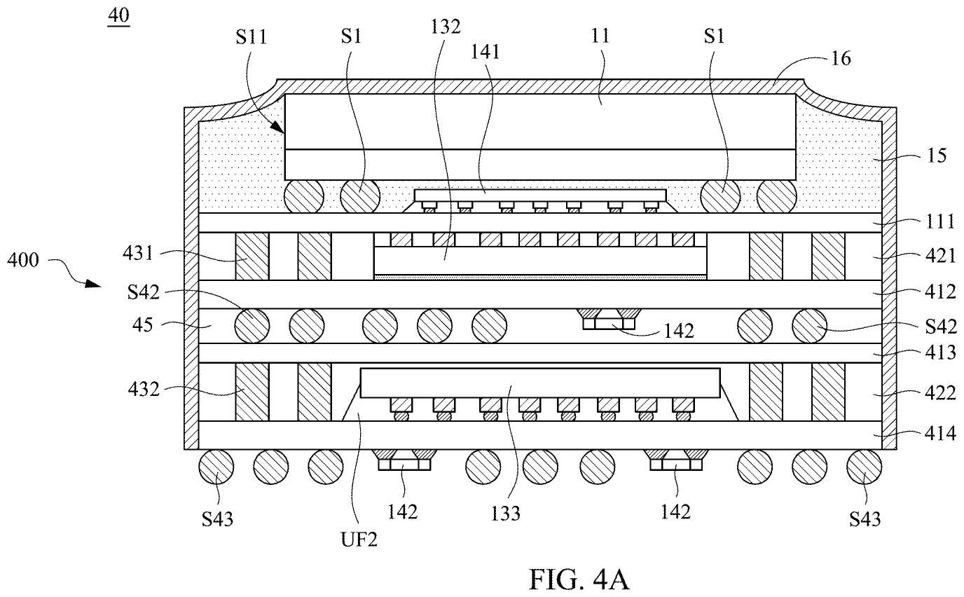

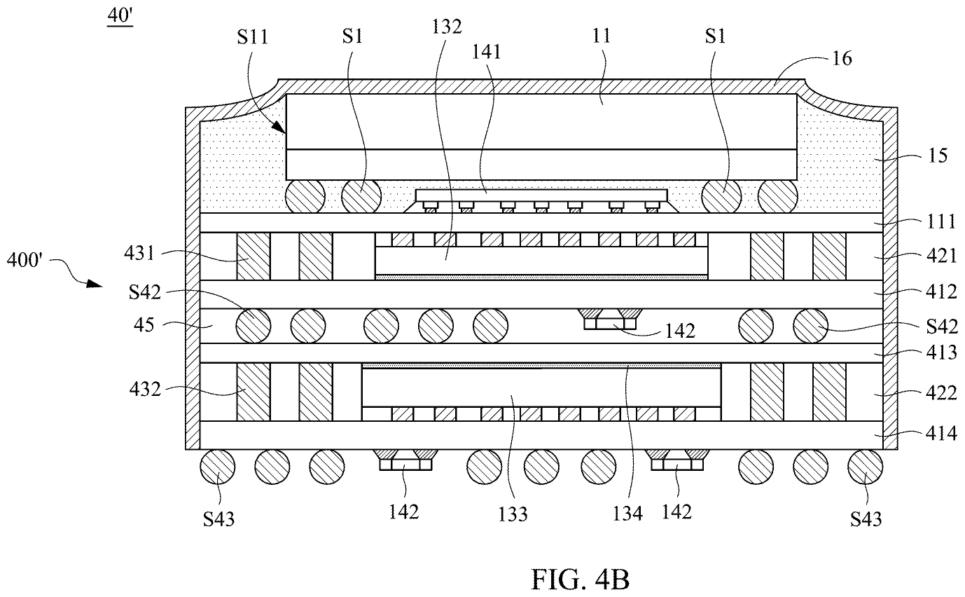

FIG. 4A is a schematic cross-sectional view of a chip package according to at least another embodiment of the present disclosure. Referring to FIG. 4A, the chip package 40 of this embodiment is similar to the aforementioned chip package 10, where the chip packages 40 and 10 include the same or similar elements. For example, the chip package 40 includes the first electronic component 11, the filling glue 15, the EMI shielding layer 16, the second electronic components 141 and 142, and a carrying part 400. The differences between the chip packages 40 and 10 are described below, and the similar features of the chip packages 40 and 10 are not repeated.

The carrying part 400 includes the first wiring structure layer 111, the second wiring structure layer 412, a third wiring structure layer 413, a fourth wiring structure layer 414, a first insulating layer 421, a second insulating layer 422, the first chip 132 and the second chips 133, where the second wiring structure layer 412, the third wiring structure layer 413 and the fourth wiring structure layer 414 are all redistribution layers, and each includes at least one wiring layer and at least one insulating layer (none of which are depicted in FIG. 4A).

The first wiring structure layer 111 to the fourth wiring structure layer 414 may have the same number of wiring layers, and the thicknesses of the insulating layer or the thicknesses of the wiring layer of the four wiring structure layers may be substantially the same as each other. Alternatively, at least two of the first wiring structure layer 111 to the fourth wiring structure layer 414 have different numbers of the wiring layers, and at least two of the first wiring structure layer 111 to the fourth wiring structure layer 414 may have significantly different thicknesses of the insulating layer or thicknesses of the wiring layer, in order to avoid or weaken warping of the carrying part 400 due to differences in the coefficients of thermal expansion.

The first chip 132 is disposed in the first insulating layer 421 and is electrically connected to the first wiring structure layer 111. The first insulating layer 421 is sandwiched between the first wiring structure layer 111 and the second wiring structure layer 412, and is located between the second insulating layer 422 and the first electronic component 11. The second chip 133 is disposed in the second insulating layer 422, where the upper surface of the second chip 133 can be covered by the second insulating layer 422.

The second chip 133 is electrically connected to the fourth wiring structure layer 414, and can be electrically connected to the fourth wiring structure layer 414 through solders (not labeled), where the gap (not labeled) between the second chip 133 and the fourth wiring structure layer 414 can be filled with the underfill UF2, as shown in FIG. 4A. The third wiring structure layer 413 is disposed on the second insulating layer 422, and the second insulating layer 422 is sandwiched between the third wiring structure layer 413 and the fourth wiring structure layer 414.

The carrying part 400 further includes multiple second solders S42, where the second solders S42 are sandwiched between the second wiring structure layer 412 and the third wiring structure layer 413, and are connected to the second wiring structure layer 412 and the third wiring structure layer 413. In this way, the second wiring structure layer 412 and the third wiring structure layer 413 can be electrically connected to each other through the second solders S42.

The carrying part 400 may further include a filling layer 45 and multiple third solders S43. The filling layer 45 fills the gap between the second wiring structure layer 412 and the third wiring structure layer 413, and covers the second solders S42. The third solders S43 are disposed on the lower surface of the fourth wiring structure layer 414, and the third solders S43 can be the same as the aforementioned second solders S42, where these third solders S43 enable the chip package 40 to be installed on an external circuit board (not shown) and electrically connected to the external circuit board.

The carrying part 400 further includes at least one first conductive pillar 431 and at least one second conductive pillar 432. The first conductive pillar 431 is disposed in the first insulating layer 421 and is located between the first wiring structure layer 111 and the second wiring structure layer 412, where the first conductive pillar 431 is connected to the first wiring structure layer 111 and the second wiring structure layer 412 so that the first wiring structure layer 111 and the second wiring structure layer 412 are electrically connected to each other. The second conductive pillar 432 is disposed in the second insulating layer 422 and is located between the third wiring structure layer 413 and the fourth wiring structure layer 414, where the second conductive pillar 432 is connected to the third wiring structure layer 413 and the fourth wiring structure layer 414 so that the third wiring structure layer 413 and the fourth wiring structure layer 414 are electrically connected to each other.

Through the first wiring structure layer 111, the second wiring structure layer 412, the third wiring structure layer 413, the fourth wiring structure layer 414, the second solders S42, the first conductive pillars 431 and the second conductive pillars 432, the first electronic component 11, the first chip 132 and the second chip 133 can be electrically connected to each other, so the electrical signals can be transmitted between the first electronic component 11, the first chip 132 and the second chip 133.

It is worth mentioning that in the embodiment shown in FIG. 4A, the second chip 133 is electrically connected to the fourth wiring structure layer 414 through the solders (not labeled), where the underfill UF2 is filled between the second chip 133 and the fourth wiring structure layer 414. However, in other embodiments, the second chip 133 may also be directly electrically connected to the fourth wiring structure layer 414 without solder, and there may not be any underfill UF2 between the second chip 133 and the fourth wiring structure layer 414.

FIG. 4B is a schematic cross-sectional view of a chip package according to at least another embodiment of the present disclosure. Referring to FIG. 4B, the chip package 40′ of this embodiment is similar to the aforementioned chip package 40. Only the differences between the chip packages 40′ and 40 are described below, and the same features of the chip packages 40′ and 40 are not repeated.

Specifically, the chip package 40′ includes a carrying part 400′, where the carrying part 400′ is similar to the aforementioned carrying part 400 shown in FIG. 4A. For example, the carrying parts 400′ and 400 also include some same elements, such as the second chip 133, the first chip 132 and the second insulating layer 422. Different from the aforementioned carrying part 400, the carrying part 400′ does not include the underfill UF2, so the second chip 133 is directly electrically connected to the fourth wiring structure layer 414 without solder. Moreover, the carrying part 400′ further includes an adhesive layer 134, where the adhesive layer 134 sandwiched between the backside of the second chip 133 and the third wiring structure layer 413 adheres to the backside of the second chip 133 and the third wiring structure layer 413, as shown in FIG. 4B.

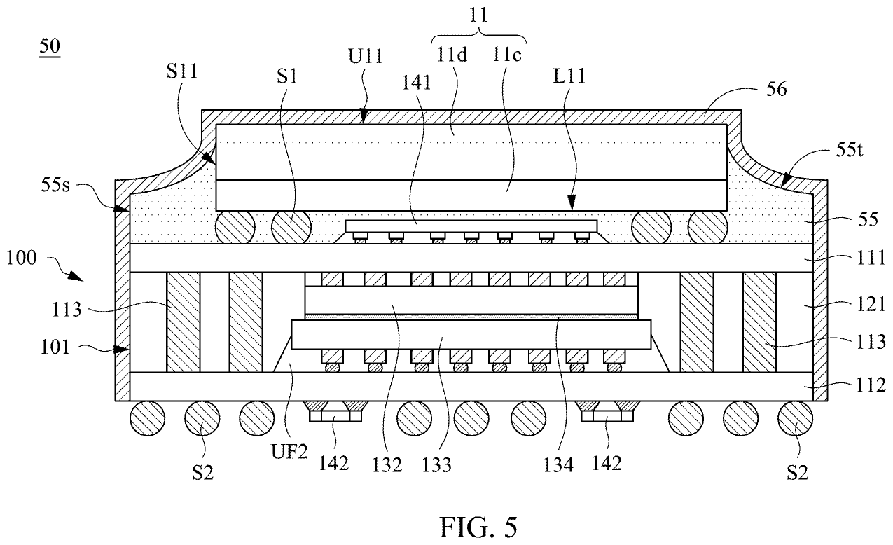

FIG. 5 is a schematic cross-sectional view of a chip package according to at least another embodiment of the present disclosure. Referring to FIG. 5, the chip package 50 of this embodiment is similar to the aforementioned chip package 10, where the chip packages 50 and 10 include the same or similar elements. The only difference between the chip packages 50 and 10 is that the filling glue 55 included in the chip package 50 does not completely cover the side S11 of the first electronic component 11. Taking FIG. 5 as an example, the filling glue 55 covers a portion of the side S11 but does not cover other portion of the side S11 close to the upper surface U11.

It can be seen from this that the filling glue 55 is not connected to the upper surface U11 of the first electronic component 11, and the first electronic component 11 protrudes from the top surface 55t of the filling glue 55. In addition, the EMI shielding layer 56 not only covers the upper surface U11 of the first electronic component 11, but also covers a portion of the side S11, as shown in FIG. 5. Furthermore, in this embodiment, the filling glue 55 covers the entire side of the carrier 11c and a portion of the side of the chip element 11d. However, in other embodiments, the filling glue 55 may cover a portion of the side of the carrier 11c but not cover the side of the chip element 11d.

Similar to the aforementioned chip package 10, the EMI shielding layer 56 can be formed by physical vapor deposition (such as sputtering or evaporation), and conformally covers the upper surface U11 and the side S11 of the first electronic component 11, the first sidewall 101 of the carrying part 100, the top surface 55t and the second sidewall 55s of the filling glue 55. The material of the filling glue 55 is the same as the material of the aforementioned filling glue 15, and the top surface 55t of the filling glue 55 is also an inclined plane, which can be a flat surface or a concave curve.

Therefore, during the process of physical vapor deposition (such as sputtering), since the top surface 55t is an inclined plane, the metal material is conducive to being deposited on the top surface 55t of the filling glue 55 so that the EMI shielding layer 56 can comprehensively cover the upper surface U11 of the first electronic component 11, the first sidewall 101 of the carrying part 100, the top surface 55t and the second sidewall 55s of the filling glue 55. In this way, the EMI shielding layer 56 can effectively shield electromagnetic waves to reduce or avoid interference of electromagnetic waves on the first electronic component 11, the first chip 132 and the second chip 133.

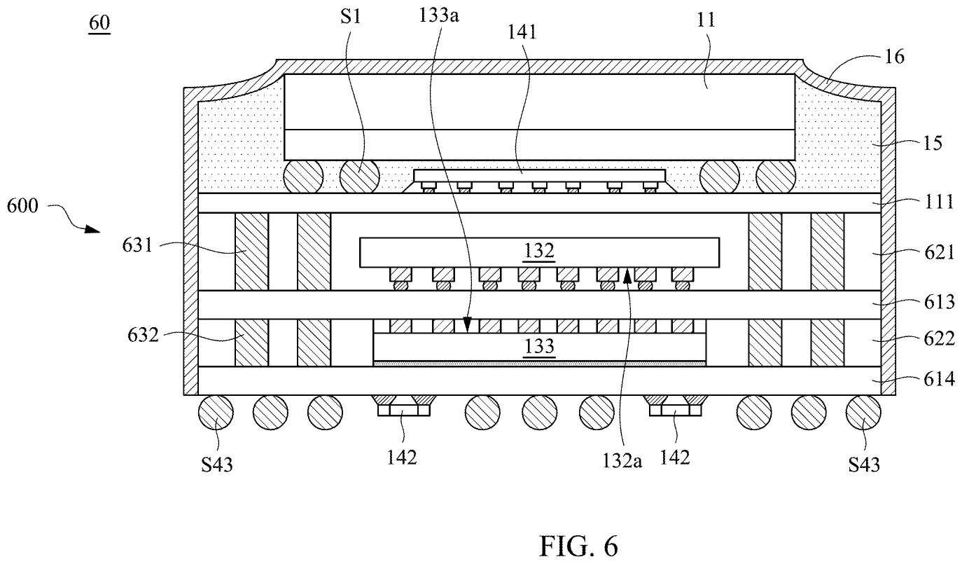

FIG. 6 is a schematic cross-sectional view of a chip package according to at least another embodiment of the present disclosure. Referring to FIG. 6, the chip package 60 of this embodiment is similar to the chip package 40 of FIG. 4A, and the chip packages 60 and 40 include the same or similar elements, such as the first chip 132, the second chip 133, and the filling glue 15. The following mainly introduces the differences between the chip packages 60 and 40, and the same features of the chip packages 60 and 40 are not repeated.

In this embodiment, the active surface 132a of the first chip 132 and the active surface 133a of the second chip 133 face each other, that is, the first chip 132 and the second chip 133 are disposed face to face with each other, where the active surfaces 132a and 133a refer to the chip surfaces having the contact pads (not shown), as shown in FIG. 6. Referring to FIGS. 4A and 6, different from the chip package 60, in the embodiment of FIG. 4A, the active surface 132a of the first chip 132 and the active surface 133a of the second chip 133 (not labeled in FIG. 4A) are back-to-back with each other, i.e., the first chip 132 and the second chip 133 in FIG. 4A are disposed back-to-back with each other.

The chip package 60 includes the first wiring structure layer 111, a second wiring structure layer 614, and a third wiring structure layer 613, where the first wiring structure layer 111, the second wiring structure layer 614, and the third wiring structure layer 613 may be redistribution layers, and the third wiring structure layer 613 is located between the first wiring structure layer 111 and the second wiring structure layer 614. In addition, the chip package 60 further includes at least one first conductive pillar 631 and at least one second conductive pillar 632.

The first conductive pillar 631 is disposed in the first insulating layer 621 and is located between the first wiring structure layer 111 and the third wiring structure layer 613, and the first conductive pillar 631 is connected to the first wiring structure layer 111 and the third wiring structure layer 613 so that the first wiring structure layer 111 and the third wiring structure layer 613 are electrically connected to each other. The second conductive pillar 632 is disposed in the second insulating layer 622 and is located between the third wiring structure layer 613 and the second wiring structure layer 614, where the second conductive pillar 632 is connected to the third wiring structure layer 613 and the second wiring structure layer 614 so that the third wiring structure layer 613 and the second wiring structure layer 614 are electrically connected to each other.

The chip package 60 includes a first insulating layer 621 and a second insulating layer 622, where the first insulating layer 621 is disposed between the first wiring structure layer 111 and the third wiring structure layer 613, and the second insulating layer 622 is disposed between the second wiring structure layer 614 and the third wiring structure layer 613. The first chip 132 is disposed in the first insulating layer 621 and is electrically connected to the third wiring structure layer 613. The second chip 133 is disposed in the second insulating layer 622 and is electrically connected to the third wiring structure layer 613. The third wiring structure layer 613 is sandwiched between the first chip 132 and the second chip 133, and the active surface 132a and 133a both face the third wiring structure layer 613.

It can be seen from this that in FIGS. 4A and 6, the first chip 132 and the second chip 133 can be arranged back-to-back (as shown in FIG. 4A) or face-to-face (as shown in FIG. 6). However, it should be noted that in other embodiments, the active surface 132a of the first chip 132 and the active surface 133a of the second chip 133 may face the same direction. For example, the active surfaces 132a and 133a both face the first electronic component 11, or face away from the first electronic component 11. Therefore, the first chip 132 and the second chip 133 are not limited to be arranged face to face or back to back.

In addition, the third wiring structure layer 613 in FIG. 6 can be replaced by the second wiring structure layer 412, the third wiring structure layer 413, the second solders S42 and the filling layer 45 in FIG. 4A. On the contrary, the second wiring structure layer 412, the third wiring structure layer 413, the second solders S42 and the filling layer 45 in FIG. 4A can also be replaced with the third wiring structure layer 613 in FIG. 6. Therefore, the third wiring structure layer 613 in FIG. 6 can be applied to the chip package 40 of FIG. 4A, and the second wiring structure layer 412, the third wiring structure layer 413, the second solders S42 and the filling layer 45 in FIG. 4A can also be applied to the chip package 60 of FIG. 6.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims.

What is claimed is:

1. A chip package, comprising:
a carrying part, having a first sidewall and comprising a first wiring structure layer and a first insulating layer, wherein the first wiring structure layer is disposed on the first insulating layer, and the first sidewall exposes the first wiring structure layer and the first insulating layer;
a first electronic component, disposed on the first wiring structure layer, wherein a gap is formed between the first electronic component and the first wiring structure layer;
a plurality of first solders, disposed in the gap and connected to the first electronic component and the first wiring structure layer; and
a filling glue, covering the first wiring structure layer and a side of the first electronic component and filling the gap, wherein the filling glue has a top surface and a second sidewall surrounding and connected to the top surface, wherein the second sidewall is flush with the first sidewall, and the top surface extends from the side of the first electronic component to the second sidewall.

2. The chip package of claim 1, wherein the filling glue has an included angle, and the included angle is located between the top surface and the second sidewall and is greater than 90 degrees.

3. The chip package of claim 1, wherein a distance between the top surface and the carrying part decreases from the side of the first electronic component toward the second sidewall.

4. The chip package of claim 1, wherein the top surface is a concave curve.

5. The chip package of claim 1, wherein the first electronic component has an upper surface and a lower surface, and the side of the first electronic component surrounds and is connected to the upper surface and the lower surface,
wherein the filling glue is connected to an edge of the upper surface, and the first solders is connected to the lower surface.

6. The chip package of claim 1, further comprises an EMI shielding layer, wherein the EMI shielding layer conformally covers the first electronic component, the first sidewall of the carrying part, the top surface and the second sidewall of the filling glue.

7. The chip package of claim 1, wherein the carrying part further comprises:
a first chip, disposed in the first insulating layer and electrically connected to the first wiring structure layer;
a second chip, disposed in the first insulating layer, wherein the first chip is located between the second chip and the first wiring structure layer;
an adhesive layer, disposed between the first chip and the second chip, and adhering to a backside of the first chip and a backside of the second chip; and
a second wiring structure layer, electrically connected to the second chip, wherein the second chip is located between the first chip and the second wiring structure layer, and the first insulating layer is sandwiched between the first wiring structure layer and the second wiring structure layer.

8. The chip package of claim 7, further comprising a second electronic component, wherein the second electronic component is disposed on the second wiring structure layer.

9. The chip package of claim 7, wherein the carrying part further comprises:
at least one conductive pillar, disposed in the first insulating layer and located between the first wiring structure layer and the second wiring structure layer, wherein the at least one conductive pillar is connected to the first wiring structure layer and the second wiring structure layer.

10. The chip package of claim 9, wherein the at least one conductive pillar comprises:
a first conductive sub-pillar, connected to the second wiring structure layer; and
a second conductive sub-pillar, stacked on the first conductive sub-pillar and connected to the first conductive sub-pillar and the first wiring structure layer, wherein the second conductive sub-pillar is located between the first conductive sub-pillar and the first wiring structure layer, and a diameter of the first conductive sub-pillar is not equal to a diameter of the second conductive sub-pillar.

11. The chip package of claim 1, further comprising a second electronic component, wherein the second electronic component is disposed on the first wiring structure layer.

12. The chip package of claim 1, wherein the carrying part further comprises:
a first chip, disposed in the first insulating layer and electrically connected to the first wiring structure layer;
a second wiring structure layer, wherein the first insulating layer is sandwiched between the first wiring structure layer and the second wiring structure layer;
a second insulating layer, wherein the first insulating layer is located between the second insulating layer and the first electronic component;
a second chip, disposed in the second insulating layer;
a third wiring structure layer, disposed on the second insulating layer;
a fourth wiring structure layer, electrically connected to the second chip, wherein the second insulating layer is sandwiched between the third wiring structure layer and the fourth wiring structure layer; and
a plurality of second solders, sandwiched between the second wiring structure layer and the third wiring structure layer.

13. The chip package of claim 12, wherein the carrying part further comprising:
at least one first conductive pillar, disposed in the first insulating layer and located between the first wiring structure layer and the second wiring structure layer, wherein the at least one first conductive pillar is connected to the first wiring structure layer and the second wiring structure layer; and
at least one second conductive pillar, disposed in the second insulating layer and located between the third wiring structure layer and the fourth wiring structure layer, wherein the at least one second conductive pillar is connected to the third wiring structure layer and the fourth wiring structure layer.

14. A method of manufacturing a chip package, comprising:
forming an initial carrying part, wherein the initial carrying part comprises a first wiring structure layer and a first insulating layer, and the first wiring structure layer is disposed on the first insulating layer;
disposing at least one first electronic component on the first wiring structure layer, wherein a gap is formed between the at least one first electronic component and the first wiring structure layer;
after disposing the at least one first electronic component on the first wiring structure layer, forming a filling material on the first wiring structure layer, wherein the filling material covers a side of the at least one first electronic component and filling the gap; and
after forming the filling material, cutting the filling material and the initial carrying part to form at least one carrying part and at least one filling glue disposed on the at least one carrying part.

15. The method of claim 14, further comprising:
after cutting the filling material and the initial carrying part, forming an EMI shielding layer, wherein the EMI shielding layer covers the at least one first electronic component, the at least one carrying part and the at least one filling glue.

16. The method of claim 14, wherein the step of forming the initial carrying part comprises:
forming a second wiring structure layer on a carrier substrate;
forming at least one conductive pillar on the second wiring structure layer;
disposing at least one first chip and at least one second chip on the second wiring structure layer, wherein a backside of the at least one first chip and a backside of the at least one second chip are adhered to each other through an adhesive layer;
after forming the at least one conductive pillar, the at least one first chip and the at least one second chip, forming the first insulating layer on the second wiring structure layer, wherein the first insulating layer covers the at least one conductive pillar, the at least one first chip and the at least one second chip; and
forming the first wiring structure layer on the first insulating layer.

17. The method of claim 16, further comprising:
after forming the first wiring structure layer, removing the carrier substrate.

18. The method of claim 16, wherein the step of forming the at least one conductive pillar comprises:
forming a first photoresist pattern on the second wiring structure layer;
forming at least one first conductive sub-pillar on the second wiring structure layer by using the first photoresist pattern as a mask;
after forming the at least one first conductive sub-pillar, forming a second photoresist pattern on the first photoresist pattern and the at least one first conductive sub-pillar, wherein the second photoresist pattern exposes the at least one first conductive sub-pillar; and
forming at least one second conductive sub-pillar on the at least one first conductive sub-pillar by using the second photoresist pattern as a mask.
